(19) United States
(12) Patent Application Publication
(10) Pub. No.: US 2011/0163308 A1
(43) Pub. Date: Jul. 7, 2011

(54) ARRAY OF VERTICAL UV LIGHT-EMITTING DIODES AND METHOD FOR PRODUCING IT

(76) Inventors: Jie Chen, Berlin (DE); Martha Christina Lux-Steiner, Berlin (DE); Christoph Aichele, Tuebingen (DE)

(21) Appl. No.: 12/666,161

(22) PCT Filed: Jul. 2, 2008
(86) PCT No.: PCT/DE2008/001108

§ 371 Date: Jun. 25, 2010

(30) Foreign Application Priority Data
Jul. 6, 2007 (DE) 10 2007 031 600.5

(51) Int. Cl. H01L 33/08; H01L 33/28; H01L 33/30; B82Y 99/00; B82Y 40/00

(52) U.S. Cl. 257/43; 257/76; 438/34; 977/762; 257/E33.025; 257/E33.019

(57) ABSTRACT

An array of vertical light-emitting diodes includes a flexible substrate-free array of vertical light-emitting diodes having a flexible polymer film forming an insulating organic layer, and a plurality of nanowires embedded in the flexible polymer film. Each of the nanowires is formed by a first and second inorganic semiconductor material or by a first organic and the first inorganic semiconductor material disposed in a respective channel in the flexible polymer film so as to form a pn-hetero-junction.

### CROSS REFERENCE TO PRIOR APPLICATIONS

This application is a U.S National Phase application under 35 U.S.C. §371 of International Application No. PCT/DE2008/001108, filed on Jul. 2, 2008 and which claims benefit to German Patent Application No. 10 2007 031 600.5, filed on Jul. 6, 2007. The International Application was published in German on Jan. 15, 2009 as WO 2009/006878 A2 under PCT Article 21(2).

### FIELD

The present invention relates to an array of vertical UV light-emitting diodes and to a method for its production.

### BACKGROUND

According to the state of the art, until now, all vertical UV light-emitting diodes in the form of nanowires and arranged in an array are based on exposed nanowires.

Appl. Phys. Lett., Vol. 85, No. 24, pp. 6004-6006, Dec. 13, 2004 and NANOLETTERS, 2005, Vol. 5, No. 10, pp. 2005-2008 describe an array with light-emitting diodes that were produced as a ZnO/polymer hetero junction in exposed nanowires on a substrate and that were subsequently embedded into a polymer layer. Due to the production method, the hetero junctions have an additional intrinsic layer.

US 2005/0224790 A1 describes a light-emitting component in which a plurality of nanowires that are created so as to be exposed and that are embedded in an insulating matrix are arranged on a substrate, whereby a pn-junction is configured as a light-emitting structure in each of the nanowires.

Although the arrangement of an intrinsic layer between the p-conducting layer and the n-conducting layer of the pn-junction is no longer necessary with this solution, this light-emitting diode array is not flexible either.

All of the solutions described so far also have in common the fact that, due to the necessary free growth of the nanowires on a substrate and/or due to their doping, the parameters of the individual light-emitting diodes fluctuate greatly.

### SUMMARY

An aspect of the present invention is to provide a flexible array of UV light-emitting diodes in which the nanowires that are structured as the pn-junction of a light-emitting diode have similar parameters.

In an embodiment, the present invention provides a flexible substrate-free array of vertical light-emitting diodes including a flexible polymer film forming an insulating organic layer, and a plurality of nanowires embedded in the flexible polymer film. Each of the nanowires is formed by a first and second inorganic semiconductor material or by a first organic and the first inorganic semiconductor material disposed in a respective channel in the flexible polymer film so as to form a pn-hetero-junction.

### BRIEF DESCRIPTION OF THE DRAWINGS

The present invention is described in greater detail below on the basis of embodiments and of the drawing in which:

The figure schematically shows a section of a flexible array according to the invention with two vertical UV light-emitting diodes.

### DETAILED DESCRIPTION

The self-supporting polymer films into which first of all, channels are formed and then filled up with semiconductor material form the foundation for the flexible array according to the present invention comprising a plurality of UV light-emitting diodes, whereby each of the LEDs functions independently of the others. Since the channels that are filled with semiconductor material and that form the nanowires are produced by means of a method at constant process parameters, the parameters of the individual LEDs are also very similar and have fewer deviations with respect to each other than in arrays that are made up of exposed nanowires.

In an embodiment of the present invention, the inorganic semiconductor material can be ZnO or GaN for the n-type, and doped ZnO or CuSCN or doped GaN or an organic material for the p-type. As a function of the thickness of the polymer film used, the thickness of the n-type or p-type semiconductor material in the channels can lie between several 100 nm and several 100 μm.

In an embodiment of the present invention, the channel having the pn-junction can have a diameter of about 40 nm to about 400 nm, and the flexible polymer film with the channels having the pn-junction can have a thickness of about 1 μm to about 25 μm.

Depending on the application area, the channels formed in the flexible polymer film can be configured so as to be cylindrical or conical.

In order to better guide the emitted light to the cathode and thus in order to improve the efficiency of the individual light-emitting diodes, a very thin light-conducting layer made of an organic or inorganic material with a thickness of a few nm to a few 10 nm can be arranged between the wall of the channels formed in the flexible polymer film and the nanowire made of semiconductor material.

In the method according to the present invention for the production of an array of vertical light-emitting diodes, first of all, continuous channels are formed in a flexible insulating polymer film, these channels are then filled one after the other with n-conducting inorganic semiconductor material and with p-conducting inorganic or organic semiconductor material in order to create nanowires, and subsequently a transparent cathode is applied onto the n-conducting semiconductor material and an anode is applied onto the p-conducting semiconductor material. The shape of the anode is selected as a function of the application.

The channels in the polymer film are formed by means of a laser beam or by means of an ion ray or chemical etching. Chemical etching in NaOH on one side or on both sides, for example, can give the channels a cylindrical or conical shape.

In an embodiment of the present invention, ZnO or GaN can be used as the n-conducting semiconductor material, and doped ZnO or doped GaN or CuSCN or organic semiconductor material can be used as the p-conducting semiconductor material.

Depending on the temperatures employed, PET film (<100° C.) or PI film (<400° C.), for example, at a thickness between about 1 μm and about 25 μm, can be used as the polymer film.

The semiconductor material for the pn-junction can be incorporated into the channels by means of RF plasma deposition or sputtering or electrochemical deposition.

In an embodiment of the present invention, before the transparent cathode is applied and before the channels are filled up with semiconductor material, a light-conducting layer of organic or inorganic material can be applied onto the inner walls of said channels, for example, at a thickness of a few nm to a few 10 nm.

The method for the production of a flexible array with UV light-emitting diodes does not entail any technologically difficult process steps and it makes use of inexpensive and non-toxic materials that allow the cost-effective production of flexible arrays of UV light-emitting diodes.

Such an array can be produced with the following process steps: continuous nanochannels 2 having a diameter of about 200 nm are formed in an 8 μm-thick polymer film 1, for example, a PET film, by means of an ion jet. This film 1 with the formed channels 2 forms the template for the flexible LED array at an LED density of about 10⁷ to 10¹⁰ cm⁻². In order to improve the efficiency, in this embodiment, before the transparent cathode 4 is applied, a 20 nm-thick light-conducting layer 3 made of TiO₂ or of another material having a high index of reflection is applied onto the wall of the channels 2, for example, by means of the ILGAR (Ion Layer Gas Reaction) method. A transparent cathode 4, for example, made of one of the known TCO materials, is applied in a thickness of several 100 nm onto one side of the polymer film 1. The transparent electrode 4 closes one side of the channels 2 that have been provided with the light-conducting layer 3 and that have now been completely filled with n-conducting ZnO 5 to a height of about 1 μm, and subsequently with p-conducting CuSCN 6 by means of electrochemical deposition. Subsequently, Ag or, once again, a TCO material is deposited as the anode layer in a thickness of several 10 nm to several 100 nm.

The present invention is not limited to embodiments described herein; reference should be had to the appended claims.

1-20. (canceled)

21. A flexible-substrate free array of vertical light-emitting diodes comprising:
a flexible polymer film forming an insulating organic layer; and
a plurality of nanowires embedded in the flexible polymer film, each of the nanowires being formed by a first and second inorganic semiconductor material or by a first organic and the first inorganic semiconductor material disposed in a respective channel in the flexible polymer film so as to form a pn-hetero-junction.

22. The array as recited in claim 21, wherein the pn-junction does not have an insulating interlayer.

23. The array as recited in claim 21, wherein the first inorganic semiconductor material is an n-type semiconductor including at least one of ZnO and GaN.

24. The array as recited in claim 21, wherein the first inorganic semiconductor material is a p-type semiconductor including at one of doped ZnO, doped CuSCN and doped GaN.

25. The array as recited in claim 21, wherein the respective channel has a diameter of about 40 nm to about 400 nm.

26. The array as recited in claim 21, wherein the flexible polymer film has a thickness of about 1 μm to about 25 μm.

27. The array as recited in claim 21, wherein the respective channel is cylindrical.

28. The array as recited in claim 21, wherein the respective channel is conical.

29. The array as recited in claim 21, further comprising a light-conducting layer disposed between a wall of the respective channel and the respective nanowire.

30. The array as recited in claim 29, wherein the light-conducting layer has a thickness of a few nm to a few 10 nm.

31. A method for producing an array of vertical light-emitting diodes, the method comprising:
forming continuous channels in a flexible insulating polymer film;
filling the channels with a p-conducting and an n-conducting semiconductor material so as to provide nanowires;
applying a transparent cathode onto the n-conducting semiconductor material; and
applying an anode onto the p-conducting semiconductor material.

32. The method as recited in claim 31, wherein the channels are formed by at least one of a laser beam, an ion ray, and chemical etching.

33. The method as recited in claim 31, wherein the channels are formed by an etching process so as to have a conical shape.

34. The method as recited in claim 31, wherein the channels are formed by an etching process so as to have a cylindrical shape.

35. The method as recited in claim 31, wherein the channels have a diameter of about 40 nm to about 400 nm.

36. The method as recited in claim 31, wherein the n-conducting semiconductor material is at least one of ZnO and GaN.

37. The method as recited in claim 31, wherein the p-conducting semiconductor material is at least one of doped ZnO, doped GaN, CuSCN and an organic semiconductor material.

38. The method as recited in claim 31, wherein the flexible insulating polymer film includes at least one of a PET film and a PI film having a thickness of about 1 μm to about 25 μm.

39. The method as recited in claim 31, wherein the filling is performed by at least one of RF plasma deposition, sputtering and electrochemical deposition.

40. The method as recited in claim 31, further comprising applying a light-conducting layer of organic or inorganic material onto an inner wall of the channels before filling the channels and before the applying the transparent cathode.

41. The method as recited in claim 40, wherein the light-conducting layer is applied in a thickness of a few nm to a few 10 nm.

42. The method as recited in claim 31, wherein the channels are filled one after the other.
